(19) United States
(12) Patent Application Publication
(10) Pub. No.: US 2006/0003541 A1
(43) Pub. Date: Jan. 5, 2006

(54) Method for forming device isolation film of semiconductor device

(75) Inventors: Hyung Suk Choi, Gyeonggi-do (KR); Bo Ryeong Wi, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 10/998,806

(22) Filed: Nov. 30, 2004

(30) Foreign Application Priority Data
Jun. 30, 2004 (KR) 10-2004-0050253

(51) Int. Cl. H01L 21/76

(52) U.S. Cl. 438/424; 438/435; 438/437

(57) ABSTRACT

A method for forming device isolation film of semiconductor device is provided, the method including sequentially forming a pad oxide layer and a pad nitride layer on a semiconductor substrate having a cell region and a peripheral circuit region, etching a predetermined region of the pad nitride layer, the pad oxide layer, and the semiconductor substrate to form a trench, forming an sidewall oxide film on a surface of the trench, etching a predetermined thickness of the sidewall oxide film in the cell region, forming a liner nitride film and a liner oxide film on the semiconductor substrate including the trench and the pad nitride layer, depositing a HDP oxide film to fill up the trench, performing a planarization process to expose the pad nitride layer, and removing the pad nitride layer.

### BACKGROUND OF THE INVENTION

1. Field of the Invention

The present invention generally relates to a method for forming device isolation film of semiconductor device and more specifically, to a method for forming device isolation film of semiconductor device wherein a relatively thin sidewall oxide film is formed in a cell region and a relatively thick sidewall oxide film is formed in a peripheral circuit region, to improve retention time characteristics, prevent a hot carrier phenomenon, and reduce stand-by current.

2. Description of the Background Art

FIGS. 1a through id are cross-sectional views illustrating a method for forming a device isolation film according to a prior art.

Referring to FIG. 1a, a pad oxide layer 20 and a pad nitride layer 30 are sequentially formed on a semiconductor substrate 10 having a cell region and a peripheral circuit region. A predetermined region of the pad nitride layer 30, the pad oxide layer 20, and the semiconductor substrate 10 is etched to form a trench 50 using the hard mask layer pattern 40 as an etching mask.

Referring to FIG. 1b, a sidewall oxide film 60 is formed on a surface of the trench 50. Generally, the sidewall oxide films 60 in the cell region and a peripheral circuit region have the same thickness.

Referring to FIG. 1c, a liner nitride film 70 and a liner oxide film 80 are sequentially formed on the entire surface of the semiconductor substrate 10 including the trench 50 and the pad nitride layer 30.

Referring to FIG. 1d, a HDP oxide film 90 is deposited to fill up the trench 50. Next, the HDP oxide film 90 is subjected to a CMP process until the pad nitride layer 30 is exposed. The pad nitride layer 30 is then removed to form a device isolation film of semiconductor device.

In accordance with the conventional method for forming device isolation film of semiconductor device, the sidewall oxide film 60 is formed to prevent generation of crystalline defects on the interface of the semiconductor substrate and HDP oxide film. The volume of the HDP oxide film expands in a subsequent heat treatment which imposes compression stress on the semiconductor substrate, thereby generating a junction leakage current. As a result, data retention time characteristics of a semiconductor device are degraded.

Moreover, a liner nitride film formed between the HDP oxide film and the semiconductor substrate reduces the compression stress applied to the semiconductor substrate and improves the data retention time characteristics. However, the liner nitride film generates hot electron traps between the sidewall oxide film and the liner nitride film to cause channel shortening and hot carrier phenomena. As a result, the leakage current characteristic of a PMOS transistor is deteriorated and the stand-by current is increased. Heating phenomenon by the leakage current degrades operation speed in a semiconductor device.

In order to solve above problems, a gate tab is formed at the channel edges where negative charges are trapped so as to prevent hot carrier effect at the channel edge. However, the gate tap decreases the channel width.

### SUMMARY OF THE INVENTION

Accordingly, it is an object of the present invention to provide a method for forming device isolation of semiconductor device wherein a relatively thin sidewall oxide film is formed in a cell region and a relatively thick sidewall oxide film is formed in a peripheral circuit region to reduce the stress applied to a semiconductor substrate by a liner nitride film and improve the retention time characteristic a semiconductor device.

Moreover, it is another object of the present invention to prevent accumulation of negative charges at the junction area of the liner nitride film and the sidewall oxide film by forming a thick sidewall oxide film in the peripheral circuit region so as to prevent hot carrier effect generated by a channel-shortening phenomenon in a pMOS transistor and reduce the stand-by current. Accordingly, the characteristic of the semiconductor device is improved.

In order to achieve above-described object, there is provided a method for forming device isolation film of semiconductor device, the method comprising the steps of:

(a) sequentially forming a pad oxide layer and a pad nitride layer on a semiconductor substrate having a cell region and a peripheral circuit region;

(b) etching a predetermined region of the pad nitride layer, the pad oxide layer, and the semiconductor substrate to form a trench;

(c) forming an sidewall oxide film on a surface of the trench;

(d) etching a predetermined thickness of the sidewall oxide film in the cell region;

(e) forming a liner nitride film and a liner oxide film on the semiconductor substrate including the trench and the pad nitride layer;

(f) depositing a HDP oxide film to fill up the trench;

(g) performing a planarization process to expose the pad nitride layer; and

(h) removing the pad nitride layer.

### BRIEF DESCRIPTION OF THE DRAWINGS

FIGS. 1a through 1d are cross-sectional views illustrating a conventional method for forming a device isolation film of semiconductor device.

FIGS. 2a through 2f are cross-sectional views illustrating a method for forming device isolation film of semiconductor device according to the present invention.

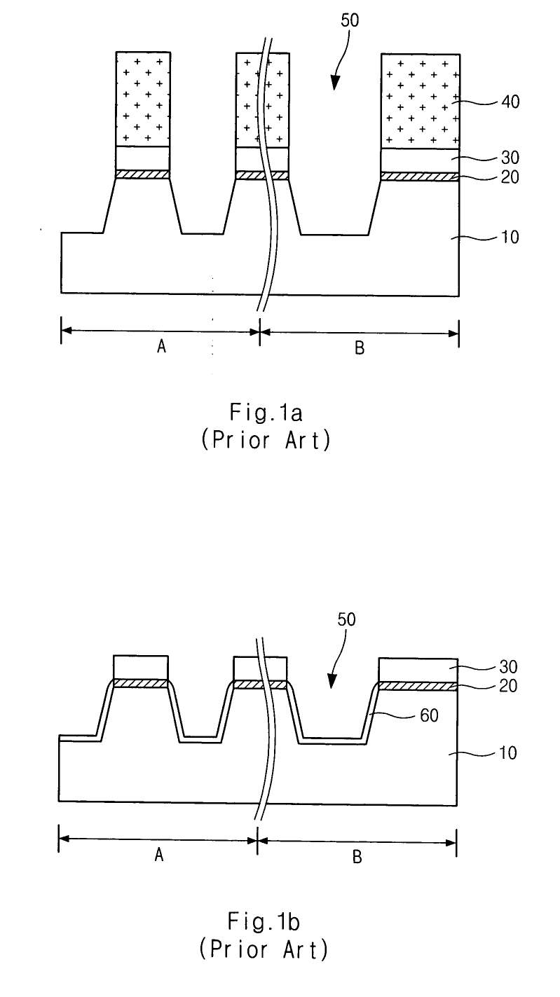

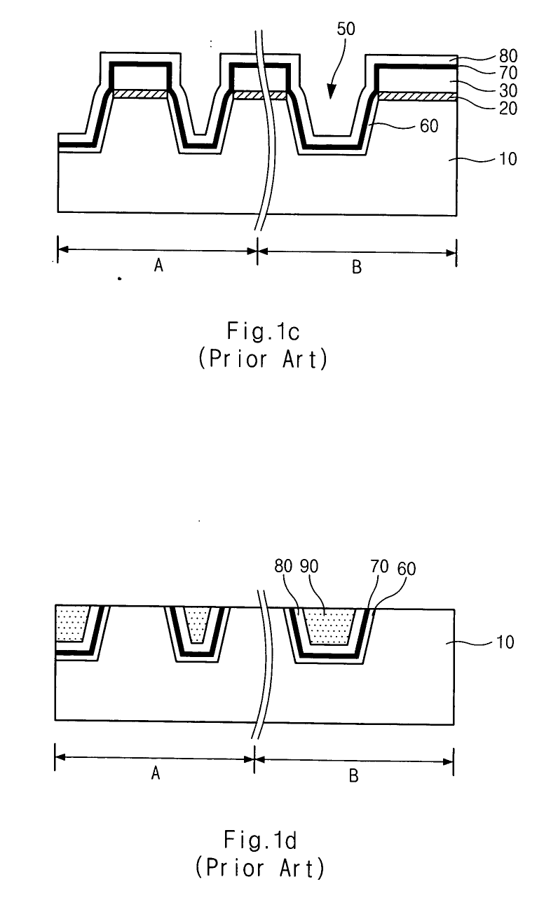

### DETAILED DESCRIPTION OF THE EXAMPLARY EMBODIMENTS

A method for forming a device isolation film of a semiconductor device in accordance with an embodiment of the present invention will now be described in detail with reference to the accompanying drawings. Wherever possible, the same reference numbers will be used throughout the drawings to refer to the same or like parts.

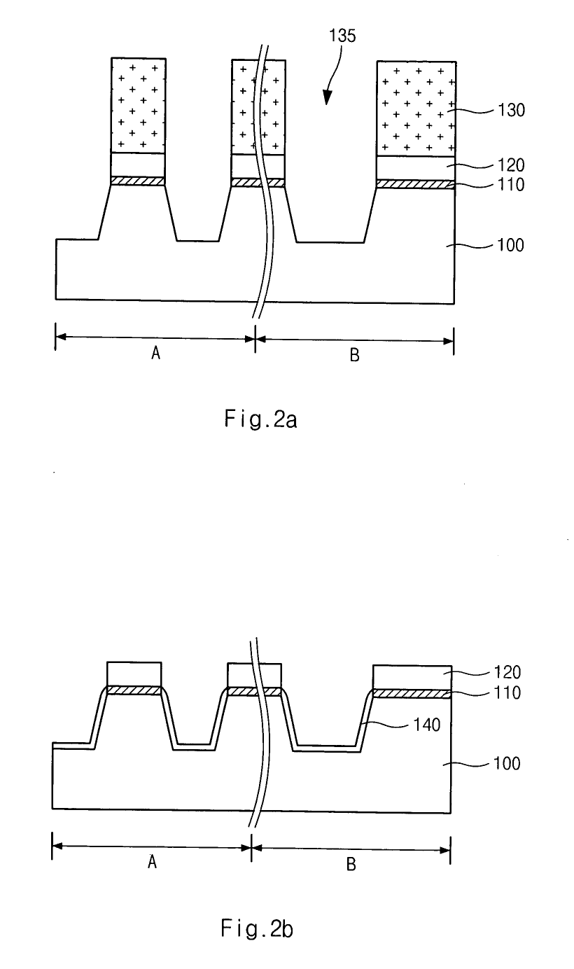

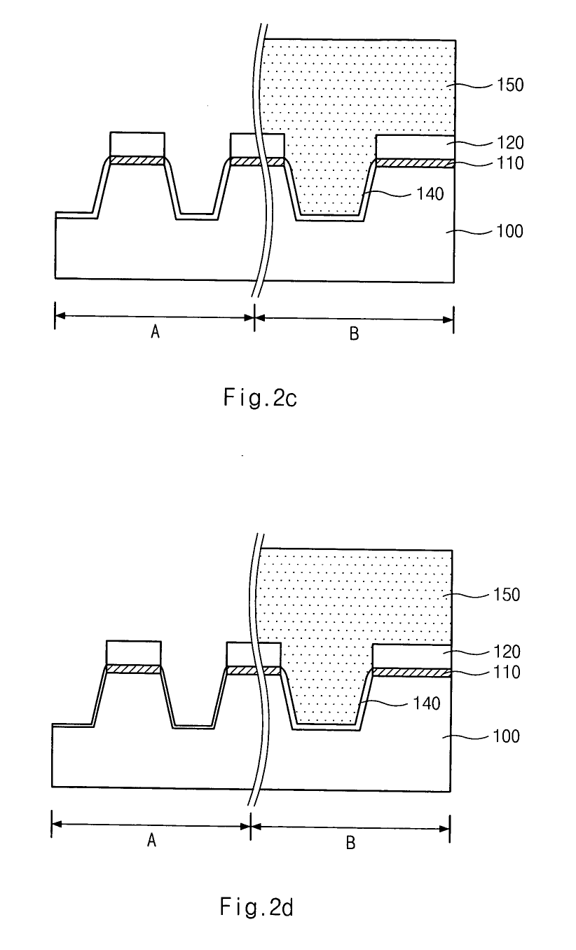

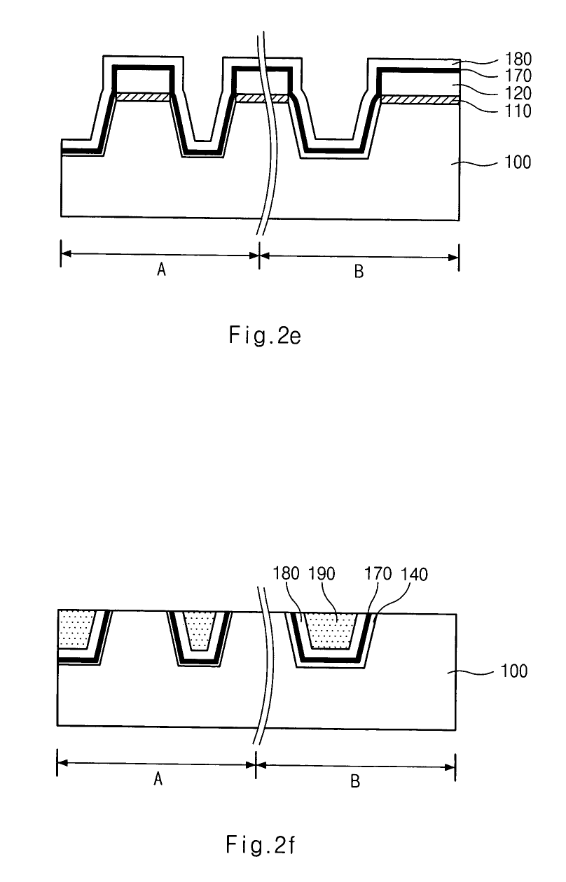

Referring to FIG. 2a, a pad oxide layer 110 and a pad nitride layer 120 are sequentially formed on a semiconductor substrate 100 having a cell region and a peripheral circuit region respectively denoted as ‘A’ and ‘B’. Next, a predetermined region of the pad nitride layer 120, the pad oxide layer 110, and the substrate 100 are etched using a photoresist pattern 130 as an etching mask to form a trench 135. The photoresist pattern 130 is then removed.

Referring to FIG. 2b, a sidewall oxide film 140 is formed on a surface of the trench 135. Preferably, the sidewall oxide film 140 has a thickness ranging from 200 Å to 300 Å.

Referring to FIG. 2c, a photoresist film pattern 150 exposing the cell region A is formed. A predetermined thickness of the sidewall oxide film 140 in the cell region A is then etched using the photoresist film pattern 150 as an etching mask. Preferably, the predetermined thickness of the sidewall oxide film 140 etched ranges from 100 Å to 150 Å. The etching process may comprise a wet etching process.

In one embodiment of the present invention, a combination of a dry etching process and a wet etching process is performed to etch the sidewall oxide film 140 in the cell region. Preferably, a thickness of the sidewall oxide film etched by the dry and wet etching processes ranges from 50 Å to 80 Å respectively.

Referring to 2e, a liner nitride film 170 and a liner oxide film 180 are sequentially formed on the entire surface of the semiconductor substrate including the trench 135 and the pad nitride layer 120. Preferably, the liner nitride film 170 and the liner oxide film 180 are formed at a temperature of 800° C. to 900° C.

Referring to 2f, a HDP oxide film 190 is deposited to fill up the trench 135, and then planarized to expose the pad nitride layer 120. The pad nitride layer 120 is then removed to form the device isolation film 190.

As described above, in accordance with the method for forming device isolation film of semiconductor device of the present invention the sidewall oxide film in the cell region is etched so that the thickness of the sidewall oxide film is less than that of the sidewall oxide film in peripheral circuit region to reduce the stress imposed to the semiconductor substrate 100 by the liner nitride film formed in a subsequent process and improve the retention time characteristic of the semiconductor device.

Also, the method prevents negative charges at a junction area of the liner nitride film and the sidewall oxide film by forming a thick sidewall oxide film in the peripheral circuit region so as to prevent hot carrier effect generated by a channel-shortening phenomenon in a pMOS transistor and reduce the stand-by current. Accordingly, the characteristics of the device are improved.

As the present invention may be embodied in several forms without departing from the spirit or scope thereof, it should also be understood that the above-described embodiments are not limited by any of the details of the foregoing description. Rather the present invention should be construed broadly as defined in the appended claims. All changes and modifications that fall within the metes and bounds of the claims, or equivalences of such metes and bounds are intended to be embraced by the appended claims.

1. A method for forming device isolation film of semiconductor device, the method comprising the steps of:
(a) sequentially forming a pad oxide layer and a pad nitride layer on a semiconductor substrate having a cell region and a peripheral circuit region;
(b) etching a predetermined region of the pad nitride layer, the pad nitride layer, and the semiconductor substrate to form a trench in the cell region and the peripheral circuit region, respectively;
(c) forming an sidewall oxide film on a surface of the trench in the cell region and the peripheral circuit region, respectively;
(d) etching of the sidewall oxide film in the cell region via a dry etching process to remove a thickness of the sidewall oxide film ranging from 50 Å to 80 Å and etching the sidewall oxide film in the cell region via a wet etching process to remove a thickness of the remaining sidewall oxide film ranging from 50 Å to 80 Å;
(e) forming a linear nitride film and a linear oxide film on the semiconductor substrate including the trench and the pad nitride layer in the cell region and the peripheral circuit region, respectively;
(f) depositing a HDP oxide film to fill up the trench in the cell region and the peripheral circuit region, respectively;
(g) performing a planerization process to expose the pad nitride layer in the cell region and the peripheral circuit region, respectively; and
(h) removing the pad nitride layer in the cell region and the peripheral circuit region, respectively.

2. (canceled)

3. The method according to claim 1, wherein the sidewall oxide film formed in step (c) has a thickness ranging from 200 Å to 300 Å.

4. (canceled)

5. (canceled)

6. (canceled)

7. The method according to claim 1, wherein the linear nitride film and the linear oxide film are formed at a temperature ranging from 800° C. to 900° C.
